(19) United States
(12) Patent Application Publication
(10) Pub. No.: US 2007/0051954 A1
(43) Pub. Date: Mar. 8, 2007

(54) TFT array substrate of TFT LCD having large storage capcitor and method for manufacturing same

(75) Inventor: Shuo-Ting Yan, Miao-Li (TW)

Correspondence Address: WEI TE CHUNG;FOXCONN INTERNATIONAL, INC., 1650 MEMOREX DRIVE, SANTA CLARA, CA, 95050, US

(73) Assignee: INNOLUX DISPLAY CORP.

(21) Appl. No.: 11/515,578

(22) Filed: Sep. 5, 2006

(30) Foreign Application Priority Data
Sep. 5, 2005 (TW) 94130316

(51) Int. Cl. H01L 29/04

(52) U.S. Cl. 257/59

(57) ABSTRACT

An exemplary thin film transistor (TFT) array substrate includes a glass substrate (430), a semiconductor layer (440) formed on the glass substrate, a gate insulating layer (407) formed on the semiconductor layer, and a plurality of gate electrodes (410) and common electrodes (411) formed on the gate insulating layer. A portion of the gate insulating layer corresponding to the common electrode includes introduced impurities to enhance a dielectric constant thereof. A method for manufacturing the TFT array substrate is also provided.

### FIELD OF THE INVENTION

This invention relates to a thin film transistor (TFT) array substrate of a TFT liquid crystal display (LCD), the TFT array substrate having a high storage capacitance. The invention also relates to a method for manufacturing the TFT array substrate.

### GENERAL BACKGROUND

A TFT LCD has the advantages of portability, low power consumption, and low radiation, and has been widely used in various portable information products such as notebooks, personal digital assistants (PDAs), video cameras and the like. Furthermore, the TFT LCD is considered by many to have the potential to completely replace CRT (cathode ray tube) monitors and televisions.

A TFT LCD usually includes a color filter substrate, a TFT array substrate, and a liquid crystal layer sandwiched between the two substrates. When a TFT LCD works, an electric field is applied to the liquid crystal molecules of the liquid crystal layer. At least some of the liquid crystal molecules change their orientations, whereby the liquid crystal layer provides anisotropic transmittance of light therethrough. Thus the amount of the light penetrating the color filter substrate is adjusted by controlling the strength of the electric field. In this way, desired pixel colors are obtained at the color filter substrate, and the arrayed combination of the pixel colors provides an image viewed on a display screen of the TFT LCD.

Normally, the TFT array substrate includes a plurality of gate lines that are parallel to each other and extend along a first direction, and a plurality of data line that are parallel to each other and extend along a second direction orthogonal to the first direction. The smallest rectangular area formed by any two adjacent gate lines together with any two adjacent data lines defines a pixel region thereat. In each pixel region, a TFT is provided in the vicinity of a respective point of intersection of one of the gate lines and one of the data lines. The TFT functions as a switching element. A pixel electrode is connected to the TFT. The color filter substrate includes a plurality of common electrodes, each common electrode corresponding to a respective one of the pixel electrodes on the TFT array substrate.

FIG. 13 is a flow chart of a typical method for manufacturing a TFT array substrate of a TFT LCD. The method includes the following steps: forming an amorphous silicon layer on a glass substrate, then crystallizing the amorphous silicon layer to form a polycrystalline silicon layer (step 101); introducing p-type impurities into the polycrystalline silicon layer to form a p-type semiconductor layer (step 102); introducing n-type impurities into a portion of the p-type semiconductor layer to form an n⁺-type semiconductor layer (step 103); forming a gate insulating layer covering the n⁺-type and p-type semiconductor layers (step 104); forming a gate electrode and a common electrode on the gate insulating layer (step 105); forming an insulator layer covering the gate and common electrodes (step 106); forming a plurality of contact holes in the insulator layer (step 107); forming a source contact electrode, a drain contact electrode, and a gate contact electrode through the contact holes, respectively (step 108); forming a planarization layer on the insulator layer (step 109); and forming a pixel electrode on the planarization layer (step 110).

FIG. 14 through FIG. 23 are schematic, side cross-sectional views of a pixel unit of a TFT array substrate, each relating to a respective one of manufacturing steps of the method of FIG. 13. The manufacturing steps are described in details as follows.

In step 101, referring to FIG. 14, this includes providing a glass substrate 300, depositing a silicon nitride layer 301 and a silicon oxide layer 302 on the glass substrate 300 in that order, depositing an amorphous silicon layer on the silicon oxide layer 302, and crystallizing the amorphous silicon layer by a laser annealing process or a rapid thermal annealing process to form a polycrystalline silicon layer 303. The silicon nitride layer 301 and the silicon oxide layer 302 function as buffer layers, and are each formed by a chemical vapor deposition (CVD) process.

In step 102, referring to FIG. 15, this includes introducing p-type impurities such as boron ions into the polycrystalline silicon layer 303 to form a p-type semiconductor layer 304.

In step 103, referring to FIG. 16, this includes forming a resist mask 306 on a portion of the p-type semiconductor layer 304, and introducing n-type impurities such as phosphorus ions into portions of the p-type semiconductor layer 304 not covered by the resist mask 306, thereby forming an n⁺-type semiconductor layer 305. The p-type semiconductor layer 304 covered with the resist mask 306 functions as an active layer of a thin film transistor (TFT).

In step 104, referring to FIG. 17, this includes removing the resist mask 306, and forming a silicon oxide layer as a gate insulating layer 307 on the p-type semiconductor layer 304, the n⁺-type semiconductor layer 305 and peripheral portions of the silicon oxide layer 302 in common.

In step 105, referring to FIG. 18, this includes depositing a first metal layer on the gate insulating layer 307, patterning the first metal layer to form a gate electrode 309 and a common electrode 308, forming a pair of lightly doped drain (LDD) regions 310 in portions of the p-type semiconductor layer 304 not covered by the gate electrode 309, and performing heat treatment to activate implanted impurities in the LDD regions 310. The LDD regions 310 are formed by using the gate electrode 309 as a mask.

In step 106, referring to FIG. 19, this includes depositing a hydrogenated silicon nitride layer and a silicon oxide layer in that order to form an insulator layer 312. The insulator layer 312 covers the gate electrode 309 and the common electrode 308.

In step 107, referring to FIG. 20, this includes forming a plurality of first contact holes 313. One of the first contact holes 313 is formed in the insulator layer 312 above the gate electrode 309. Two other first contact holes 313 are formed in the insulator layer 312 in common with the gate insulating layer 307, above two portions of the n⁺-type semiconductor layer 305 at opposite sides of the gate electrode 309 respectively. The first contact holes 313 are formed by photolithography and dry etching (anisotropic etching) processes.

In step 108, referring to FIG. 21, this includes forming a second metal layer on the insulator layer 312, and patterning the second metal layer to form a source contact electrode 314, a drain contact electrode 316, and a gate contact electrode 315.

In step 109, referring to FIG. 22, this includes forming a planarization layer 317 on the insulator layer 312 to cover the source contact electrode 314, the drain contact electrode 316 and the gate contact electrode 315, and forming a second contact hole 318 in the planarization layer 317 over the drain contact electrode 316 to expose the drain contact electrode 316. The second contact hole 318 is formed by photolithography and dry etching (anisotropic etching) processes.

In step 110, referring to FIG. 23, this includes depositing an indium-tin oxide (ITO) layer on the planarization layer 317 to cover the drain contact electrode 316, and patterning the ITO layer to form a pixel electrode 319 connected to the drain contact electrode 316 through the second contact hole 318.

Thus, the TFT array substrate as described above is obtained. The gate insulating layer 307 together with the n⁺-type semiconductor layer 305 and the common electrode 308 constitutes a storage capacitor C_{S} (see below).

FIG. 24 is a top plan equivalent circuit diagram of a pixel unit of the above-described TFT LCD. A gate electrode “g”, a source electrode “s”, and a drain electrode “d” of a TFT 2 are connected to a gate line 3, a data line 1, and a pixel electrode “P” respectively. Liquid crystal material sandwiched between the pixel electrode “P” and a common electrode “Com” on the color filter substrate (not shown) is represented as a liquid crystal capacitor C_{LC}. A storage capacitor C_{S} is connected in parallel with the liquid crystal capacitance C_{LC}. C_{PD} is a parasitic capacitor formed between the data line 1 and the pixel electrode “P”.

When the TFT LCD works, the gate line 3 is scanned by a scanning signal in a predetermined period time at a forepart of an image time frame. Thus, the TFT 2 connected to the gate line 3 switches to be in an activated state. When the gate line 3 is thus scanned, a gradation voltage corresponding to image data from an external circuit is provided through the data line 1 and the activated TFT 2 to the pixel electrode “P”. The potential of the common electrode “Com” is set at a constant potential. The gradation voltage applied to the pixel electrode “P” is used to control the amount of light transmitting through the pixel. After the gate line 3 has been scanned in the frame, the gradation voltage is retained by the liquid crystal capacitance C_{LC} and the storage capacitor C_{S} as a pixel electrode voltage.

However, after the gate line 3 has been scanned in the frame, a plurality of the gradation voltages on the data line 1 that are transmitted to other pixels can influence the pixel electrode voltage on the pixel electrode “P” via the parasitic capacitor C_{PD}. Thus, the quality of a corresponding image displayed on the display screen of the TFT LCD may be impaired. A change voltage V_{PIXEL} of the pixel electrode voltage caused by the gradation voltages of the data line 1 is calculated according to the following formula:

$${V}_{PIXEL} = \frac{{V}_{Data} \times {C}_{PD}}{{C}_{PD} + {C}_{LC} + {C}_{S}}$$

C_{PD} represents the capacitance of the parasitic capacitor C_{PD} between the gate line 3 and the pixel electrode “P”. C_{LC} represents the capacitance of the liquid crystal capacitor C_{LC}. C_{S} represents the capacitance of the storage capacitor C_{S}. V_{Data} represents gradation voltages on the data line 1. According to the formula above, in order to reduce the change voltage V_{PIXEL} of the pixel electrode to improve the quality of the corresponding image displayed on the display screen of the TFT LCD, the capacitance of the storage capacitor C_{S} normally needs to be increased.

What is needed, therefore, is a TFT array substrate of a TFT LCD and a method for manufacturing the TFT array substrate that overcome the above-described deficiencies.

### SUMMARY

In a preferred embodiment, a TFT array substrate of a TFT LCD includes a glass substrate, a semiconductor layer formed on the glass substrate, a gate insulating layer formed on the semiconductor layer, and a plurality of gate electrodes and common electrodes formed on the gate insulating layer. A portion of the gate insulating layer corresponding to the common electrode includes introduced impurities to enhance a dielectric constant thereof.

A method for manufacturing the TFT array substrate is also provided. The method includes the steps of: forming a semiconductor layer over a glass substrate; forming an insulating layer on the semiconductor layer; introducing impurities into a plurality of portions of the insulating layer; and forming a plurality of gate electrodes and a plurality of common electrodes on the insulating layer. The portions of the insulating layer corresponding to the common electrodes are doped with impurities to enhance a dielectric constant thereof.

Other advantages and novel features will become more apparent from the following detailed description when taken in conjunction with the accompanying drawings.

### BRIEF DESCRIPTION OF THE DRAWINGS

FIG. 1 is a flow chart of a method for manufacturing a TFT array substrate of a TFT LCD according to a preferred embodiment of the present invention.

FIG. 2 through FIG. 12 are schematic, side cross-sectional views of a pixel unit of a TFT array substrate, each relating to a respective one of manufacturing steps of the method of FIG. 1.

FIG. 13 is a flow chart of a conventional method for manufacturing a TFT array substrate of a TFT LCD.

FIG. 14 through FIG. 23 are schematic, side cross-sectional views of a pixel unit of a TFT array substrate, each relating to a respective one of manufacturing steps of the method of FIG. 13.

FIG. 24 is a top plan equivalent circuit diagram of the pixel unit of the TFT array substrate of the TFT LCD manufactured according to the method of FIG. 13.

### DETAILED DESCRIPTION OF PREFERRED EMBODIMENTS

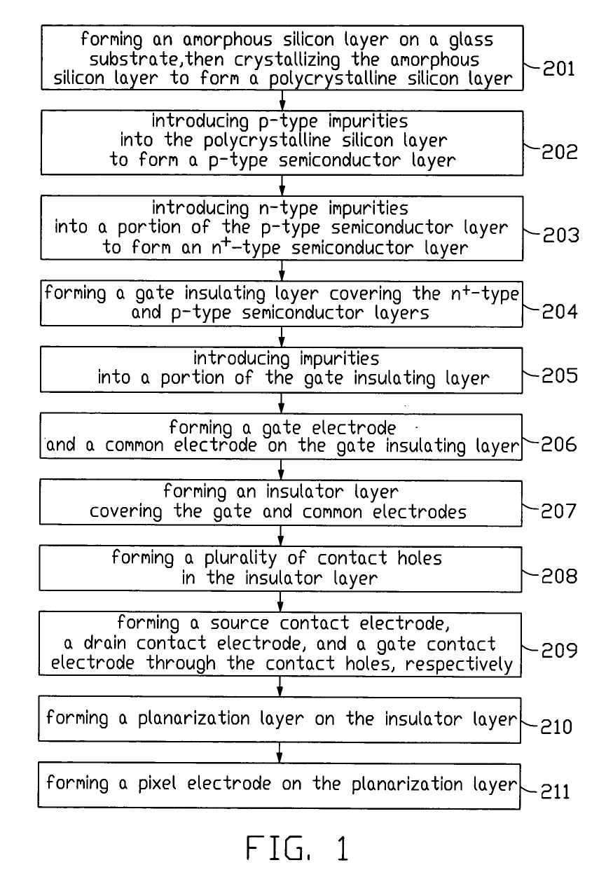

FIG. 1 is a flow chart of a method for manufacturing a TFT array substrate of a TFT LCD according to a preferred embodiment of the present invention. The method includes the following steps: forming an amorphous silicon layer on a glass substrate, then crystallizing the amorphous silicon layer to form a polycrystalline silicon layer (step 201); introducing p-type impurities into the polycrystalline silicon layer to form a p-type semiconductor layer (step 202); introducing n-type impurities into a portion of the p-type semiconductor layer to form an n⁺-type semiconductor layer (step 203); forming a gate insulating layer covering the n⁺-type and p-type semiconductor layers (step 204); introducing impurities into a portion of the insulating layer (step 205); forming a gate electrode and a common electrode on the gate insulating layer (step 206); forming an insulator layer covering the gate and common electrodes (step 207); forming a plurality of contact holes in the insulator layer (step 208); forming a source contact electrode, a drain contact electrode, and a gate contact electrode through the contact holes, respectively (step 209); forming a planarization layer on the insulating layer (step 210); and forming a pixel electrode on the planarization layer (step 211).

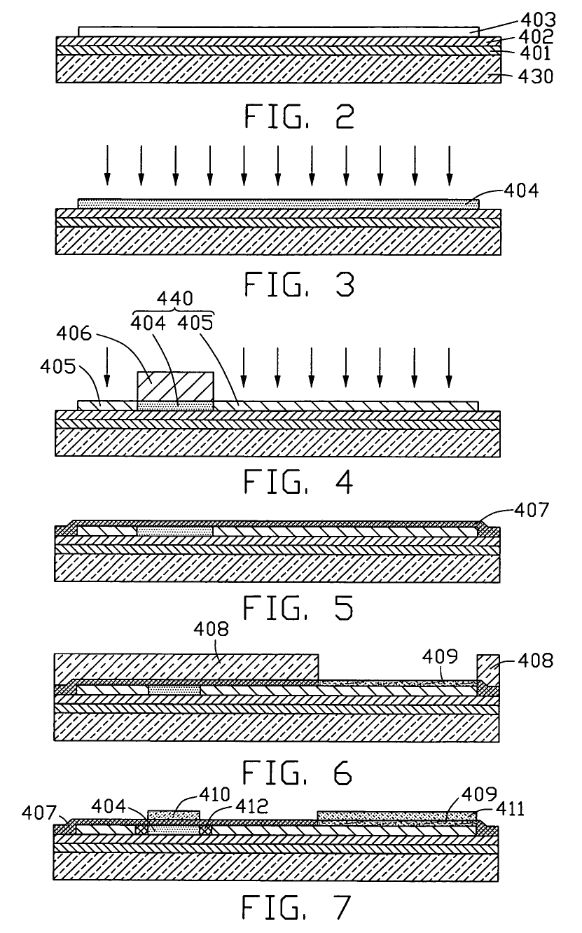

FIG. 2 through FIG. 12 are schematic, side cross-sectional views of a pixel unit of a TFT array substrate, each relating to a respective one of manufacturing steps of the method of FIG. 1. The manufacturing steps are described in detail as follows:

In step 201, referring to FIG. 2, this includes providing a glass substrate 430, depositing a silicon nitride layer 401 and a silicon oxide layer 402 on the glass substrate 430 in that order, depositing an amorphous silicon layer on the silicon oxide layer 402, and crystallizing the amorphous silicon layer by a laser annealing process or a rapid thermal annealing process to form a polycrystalline silicon layer 403. The silicon nitride layer 401 and the silicon oxide layer 402 function as buffer layers, and each are formed by a chemical vapor deposition (CVD) method.

In step 202, referring to FIG. 3, this includes introducing p-type impurities such as boron ions into the polycrystalline silicon layer 403 to form a p-type semiconductor layer 404.

In step 203, referring to FIG. 4, this includes forming a resist mask 406 on a portion of the p-type semiconductor layer 404, and introducing n-type impurities such as phosphorus ions into portions of the p-type semiconductor layer 404 not covered by the resist mask 406, thereby forming an n⁺-type semiconductor layer 405. The p-type semiconductor layer 404 covered by the resist mask 406 functions as an active layer of a thin film transistor (TFT). The p-type semiconductor layer 404 together with the n⁺-type semiconductor layer 405 are defined to be a semiconductor layer 440.

In step 204, referring to FIG. 5, this includes removing the resist mask 406, and forming a silicon oxide layer as a gate insulating layer 407 on the semiconductor layer 440 and peripheral portions of the silicon oxide layer 402 in common.

In step 205, referring to FIG. 6, this includes depositing a silicon nitride layer 408 on the gate insulating layer 407, patterning the silicon nitride layer 408 and exposing a portion 409 of the gate insulating layer 407, introducing impurities such as nitrogen ions into the exposed portion 409 of the gate insulating layer 407, removing the silicon nitride layer 408, and performing a normal temperature process to reduce or eliminate a defection of the gate insulating layer 407 which may be caused by the introduced impurities. The impurities are introduced into the exposed portion 409 of the gate insulating layer 407 by an ion implantation process or a chemical vapor deposition (CVD) process such as plasma CVD, low pressure CVD, or normal pressure CVD. Preferably, the impurities can further or alternatively be selected from the group consisting of carbon, fluorine, silicon, and germanium oxide. Generally, the impurities can further or alternatively be selected from the group consisting of chlorine, bromine, sulfur, iodine, hydrogen, phosphorus, tellurium, boron, and arsenic.

In step 206, referring to FIG. 7, this includes depositing a first metal layer on the gate insulating layer 407, patterning the first metal layer to form a gate electrode 410 and a common electrode 411, forming a pair of LDD (lightly doped drain) regions 412 in portions of the p-type semiconductor layer 404 not covered by the gate electrode 410, and performing a heat treatment to activate the introduced impurities. The LDD region 404 is formed by using the gate electrode 410 as a mask. The common electrode 411 covers the portion 409 of the gate insulating layer 407 into which the impurities were introduced. The gate electrode 410 is located on a central portion of the p-type semiconductor layer 404. A material of the first metal layer can be aluminum or copper. Accordingly, the gate electrode 410 and the common electrode 411 can be made of aluminum or copper.

In step 207, referring to FIG. 8, this includes depositing a hydrogenated silicon nitride layer and a silicon oxide layer in that order to form an insulator layer 413. The insulator layer 413 covers the gate electrode 410 and the common electrode 411.

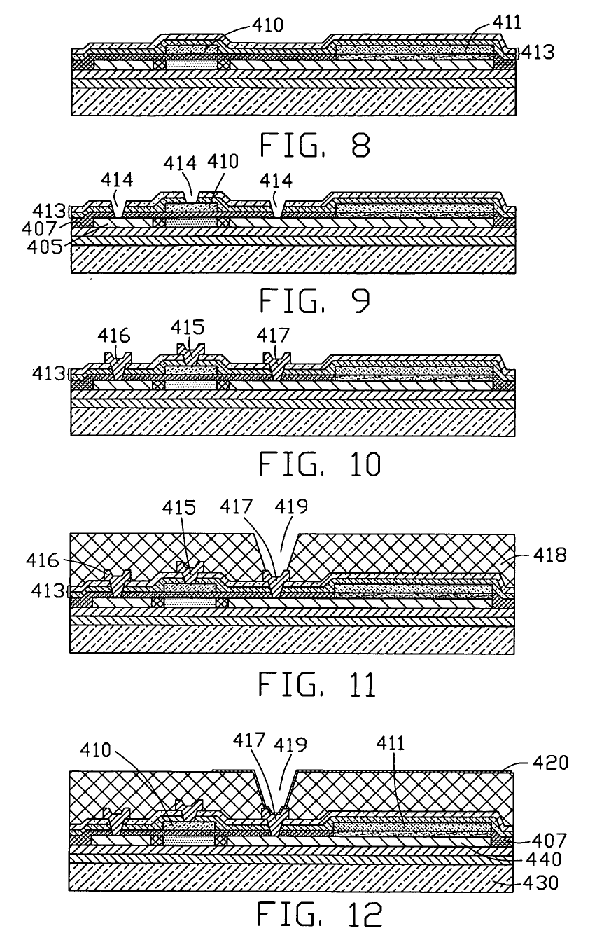

In step 208, referring to FIG. 9, this includes forming a plurality of first contact holes 414 in the insulator layer 413. One of the first contact holes 414 is formed in the insulator layer 413 above the gate electrode 410. Two other first contact holes 414 are formed in the insulator layer 413 in common with the gate insulating layer 407, above two portions of the n⁺-type semiconductor layer 405 at opposite sides of the gate electrode 410 respectively. The first contact holes 414 are formed by photolithography and dry etching (anisotropic etching) processes.

In step 209, referring to FIG. 10, this includes forming a second metal layer on the insulator layer 413, and patterning the second metal layer to form a source contact electrode 416, a drain contact electrode 417, and a gate contact electrode 415.

In step 210, referring to FIG. 11, this includes forming a planarization layer 418 on the insulator layer 413 to cover the source contact electrode 416, the drain contact electrode 417 and the gate contact electrode 415, and forming a second contact hole 419 in the planarization layer 418 over the drain contact electrode 417 to expose the drain contact electrode 417. The second contact hole 419 is formed by photolithography and dry etching (anisotropic etching) processes.

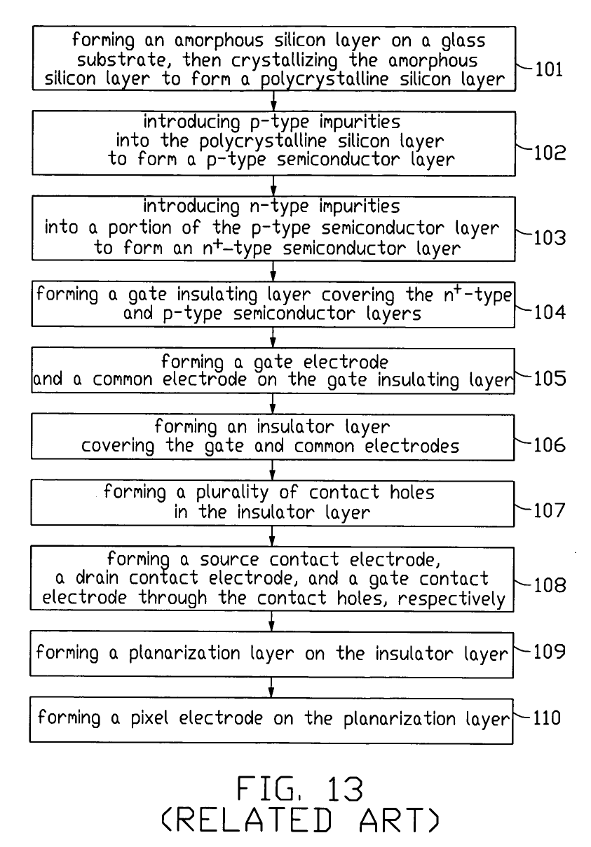

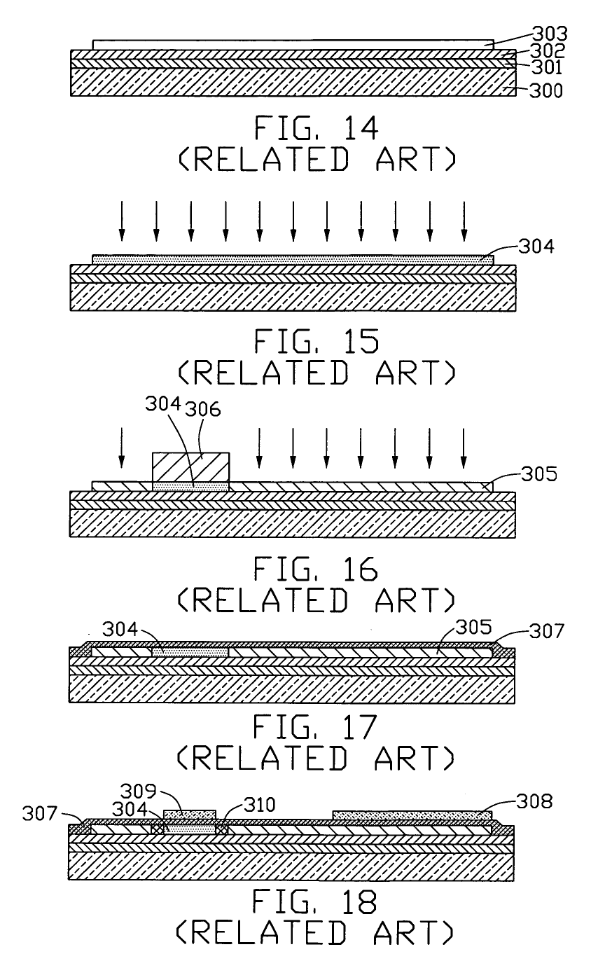

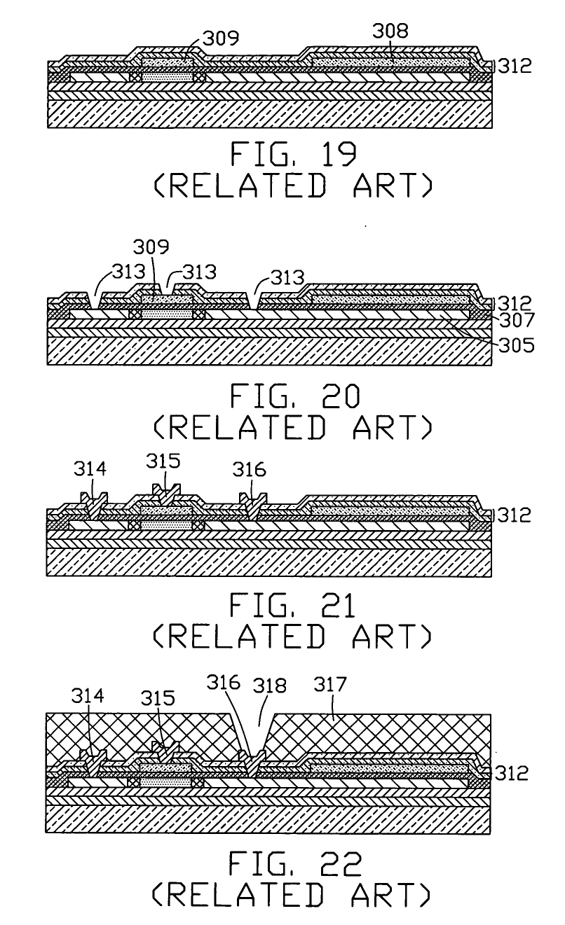

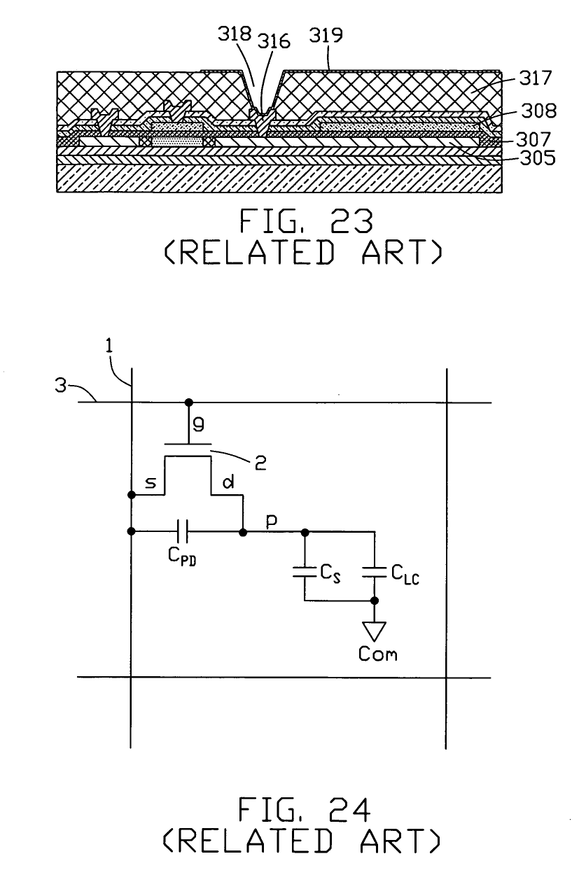

In step 211, referring to FIG. 12, this includes depositing an ITO layer on the planarization layer 418 to cover the drain contact electrode 417, and patterning the ITO layer to form a pixel electrode 420 connected to the drain contact electrode 417 through the second contact hole 419.

Thus, a plurality of pixel units of the above-described TFT array substrate of a TFT LCD is obtained. Each pixel unit of the TFT array substrate includes the glass substrate 430, the semiconductor layer 440 formed on the glass substrate 430, the gate insulating layer 407 formed on the semiconductor layer 440, and the gate electrode 410 and the common electrode 411 formed on the gate insulating layer 407. A portion of the gate insulating layer 407 covered by the common electrode 411 has the introduced impurities, to enhance a dielectric constant thereof. When the impurities are the nitride ions, the portion 409 of the gate insulating layer 407 covered by the common electrode 411 is known as a silicon oxynitride layer.

A dielectric constant of the silicon oxynitride layer is proportional to a concentration of the nitride ion distribution in the original silicon oxide layer. The dielectric constant of the silicon oxynitride layer can be controlled to be in the range from 3.9 to 7.9—larger than a dielectric constant of the original silicon oxide layer. Therefore a capacitance of a storage capacitor (not labeled) which includes the common electrode 411, the semiconductor layer 440, and the sandwiched silicon oxynitride layer is larger than that of the capacitor Cs of the above-described conventional TFT LCD which includes the common electrode 308, the semiconductor layer 307, and the sandwiched silicon oxide layer 302. Thus a change voltage of a pixel electrode (not shown) of the pixel unit at a corresponding color filter substrate (not shown) of the TFT LCD caused by gradation voltages on a corresponding data line is reduced because of the larger capacitance of the storage capacitor (not labeled). Therefore the quality of a corresponding image displayed on a display screen of the TFT LCD is improved.

It is to be understood, however, that even though numerous characteristics and advantages of the present embodiments have been set out in the foregoing description, together with details of the structures and functions of the embodiments, the disclosure is illustrative only, and changes may be made in detail, especially in matters of shape, size, and arrangement of parts within the principles of the invention to the full extent indicated by the broad general meaning of the terms in which the appended claims are expressed.

What is claimed is:

1. A thin film transistor (TFT) array substrate, comprising:
a glass substrate;
a semiconductor layer formed on the glass substrate;
a gate insulating layer formed on the semiconductor layer; and
a plurality of gate electrodes and common electrodes formed on the gate insulating layer;
wherein a portion of the gate insulating layer corresponding to the common electrode comprises introduced impurities to enhance a dielectric constant thereof.

2. The TFT array substrate as claimed in claim 1, wherein said portion of the gate insulating layer is covered by the common electrode.

3. The TFT array substrate as claimed in claim 1, wherein the gate insulating layer is made of silicon oxide.

4. The TFT array substrate as claimed in claim 3, wherein the impurities comprise nitrogen ions.

5. The TFT array substrate as claimed in claim 3, wherein the impurities are selected from the group consisting of carbon, fluorine, silicon, and germanium oxide.

6. The TFT array substrate as claimed in claim 3, wherein the impurities are selected from the group consisting of chlorine, bromine, sulfur, iodine, hydrogen, phosphorus, tellurium, boron, and arsenic.

7. The TFT array substrate as claimed in claim 1, wherein the gate electrodes and the common electrodes are made of metal material such as aluminum or copper.

8. The TFT array substrate as claimed in claim 7, wherein the gate electrodes and the common electrodes are made of aluminum or copper.

9. The TFT array substrate as claimed in claim 1, wherein the semiconductor comprises a p-type semiconductor layer and an n⁺-type semiconductor layer.

10. The TFT array substrate as claimed in claim 1, wherein a dielectric constant of the portion of the gate insulating layer doped with the impurities is in the range from 3.9 to 7.9.

11. A method for manufacturing a thin film transistor (TFT) array substrate, comprising the steps of:
forming a semiconductor layer over a glass substrate;
forming an insulating layer on the semiconductor layer;
introducing impurities into a plurality of portions of the insulating layer; and
forming a plurality of gate electrodes and a plurality of common electrodes on the insulating layer;
wherein the portions of the insulating layer corresponding to the common electrodes are doped with impurities to enhance a dielectric constant thereof.

12. The method for manufacturing a TFT array substrate as claimed in claim 10, wherein the common electrodes cover the portions of the insulating layer doped with the impurities.

13. The method for manufacturing a TFT array substrate as claimed in claim 10, wherein the impurities are introduced into the portions of the insulating layer by a chemical vapor deposition (CVD) process.

14. The method for manufacturing a TFT array substrate as claimed in claim 13, wherein the impurities are introduced into the portions of the insulating layer by a plasma CVD process, a low pressure CVD process, or a normal pressure CVD process.

15. The method for manufacturing a TFT array substrate as claimed in claim 10, wherein the impurities are introduced into the portions of the insulating layer by an ion implantation process.

16. The method for manufacturing a TFT array substrate as claimed in claim 10, wherein the impurities are selected from the group consisting of nitrogen, carbon, fluorine, silicon, and germanium oxide.

17. The method for manufacturing a TFT array substrate as claimed in claim 10, wherein the impurities are selected from the group consisting of chlorine, bromine, sulfur, iodine, hydrogen, phosphorus, tellurium, boron, and arsenic.

18. The method for manufacturing a TFT array substrate as claimed in claim 10, wherein the gate electrodes and the common electrodes are made of metal material.

19. The method for manufacturing a TFT array substrate as claimed in claim 18, wherein the gate electrodes and the common electrodes are made of aluminum or copper.

20. The method for manufacturing a TFT array substrate as claimed in claim 10, wherein a dielectric constant of the portion of the gate insulating layer doped with the impurities is in the range from 3.9 to 7.9.
